(19) United States
(12) Patent Application Publication
(10) Pub. No.: US 2001/0042880 A1
(43) Pub. Date: Nov. 22, 2001

(54) DRAM CELL WITH ACTIVE AREA RECLAIM

(76) Inventors: RAMA DIVAKARUNI, MIDDLETOWN, NY (US); WILLIAM H. MA, FISHKILL, NY (US); BYEONGJU PARK, WAPPINGERS FALLS, NY (US)

Correspondence Address: KERVIN R CASEY, RATNER & PRESTIA SUITE 301, ONE WESTLAKES BERWYN, P O BO X 980, VALLEY FORGE, PA, 194820980

(21) Appl. No.: 09/396,932

(22) Filed: Sep. 15, 1999

(51) Int. Cl. H01L 27/108

(52) U.S. Cl. 257/301

(57) ABSTRACT

A dynamic random-access memory (DRAM) cell comprising a trench capacitor and an access transistor and a process of manufacturing the cell. The trench capacitor is formed in a trench and is positioned at the bottom of the trench. The access transistor has an active area formed in the trench adjacent the trench capacitor and adjacent the top surface of the substrate. The active area provides an electrical connection with the trench capacitor. The DRAM cell design reclaims the active area above the trench capacitor.

### TECHNICAL FIELD

The present invention relates generally to storage devices. More particularly, this invention relates to a dynamic random-access memory (DRAM) cell having active area reclaim and a process of manufacturing the cell.

### BACKGROUND OF THE INVENTION

Dynamic random-access memory (DRAM) cells are composed of two main components, a storage capacitor (which stores charge) and an access transistor (which transfers charge to and from the capacitor). The capacitor may be either planar (on the surface) or trench (etched into the semiconductor substrate). In the semiconductor industry where there is an increased demand for memory storage capacity coupled with an ever-decreasing chip size, the trench capacitor layout is favored over the planar capacitor design because this particular configuration provides a dramatic reduction in the space required for the capacitor without sacrificing capacitance.

A very important and extremely delicate element in the DRAM cell is the electrical connection made between the storage trench and the access transistor. Such a contact is often referred to in the art as a self-aligned conductive strap. This strap (which may be on the surface or may be buried) is formed at the intersection of the storage trench and the junction of the array device by dopants which, through a thermal processing step, are outdiffused from the highly doped polysilicon fill (located in the storage trench) into the substrate (from which the trench was cut).

One such method for preparing a self-aligned buried strap in a 256 Mb DRAM cell is illustrated in U.S. Pat. No. 5,360,758, titled “Self-Aligned Buried Strap For Trench Type Dram Devices” and issued to Bronner et al. This method uses a polysilicon strap which connects the collar at the top of the capacitor to the pass transistor of the cell. The strap is formed from a blanket deposition of strap material that is subsequently removed from top surfaces by further etching processes. The strap is formed without the need for an additional mask, commonly practiced in the art, by forming a shallow trench isolation (STI) region to define the strap.

A 256 Mb trench DRAM cell equipped with a conventional strap is depicted in FIG. 1. The structure consists of a trench capacitor 10 which is etched into a single crystal P-doped silicon substrate 1. The lower level 16A of the trench 12 is typically filled with an N-doped polysilicon material. Alternatively, the trench 12 may be filled with a P-doped polysilicon material, should P-doping be required. The trench 12 also has a storage node 16B which is isolated from the P-doped substrate 1 by an insulating node dielectric barrier 26. The transistor 30 has a gate 32, a gate oxide 33, a source 34, and a drain 36.

The storage node 16B of the trench capacitor 10 is connected to the transistor 30 by a self-aligned buried strap 16C. It has been found that the strap 16C should be as small as possible. Ideally, the strap 16C should protrude less than 0.1 μm laterally into the substrate 1 and vertically no more than the thickness of the shallow trench isolation (STI) region 46 which isolates this cell from adjacent cells. Typically, the strap 16C that connects the storage node 16B to the source 34 in a DRAM cell is formed using a conventional thermal process which allows the N- or P-type dopants present in the lower level 16A of the trench 12 to diff-use upward through the storage node 16B (which is undoped and made of polysilicon) and into the P-doped substrate 1.

As the DRAM cell size continues to shrink in each generation, the outdiffusion of the dopants from the trench through the buried strap area into the active area adversely affects the transfer gate characteristics. In addition, in conventional designs such as the design illustrated FIG. 1, the area 15 above the trench capacitor 10 and buried strap 16C is not used for any purpose other than forming the connection between the trench capacitor 10 and the transistor 30. Therefore, the area 15 is a wasted section of valuable silicon real estate. Given the demand for smaller chip dimensions, there is a need to use all areas of the valuable silicon real estate. Thus, there remains a need for a DRAM design which reclaims the active area 15 above the trench capacitor 10.

### SUMMARY OF THE INVENTION

It is an object of the present invention, therefore, to provide a DRAM cell design and method of manufacturing the cell that reclaim the active area above the trench capacitor. A related object is to position the transfer gate closer to the trench than in conventional DRAM cell designs. Other objects will become apparent in the detailed description of the invention below.

To overcome the shortcomings of conventional DRAM cell designs, a new DRAM cell design is provided. The present invention provides a DRAM cell comprising a trench capacitor and an access transistor. The trench capacitor is formed in, and is positioned at the bottom of, a trench. The access transistor has an active area disposed in the trench and adjacent the substrate top surface, the active area being in electrical connection with the trench capacitor. Thus, viewed from the top, one of the active areas of the access transistor either fully or partially overlaps the trench capacitor. The electrical connection between the trench capacitor and the active area is formed automatically during the epitaxial reclaim process. In addition, the transfer gate of the DRAM cell can be located closer to the trench than that of conventional DRAM cells.

The present invention also provides a process for manufacturing the DRAM cell of the invention. The process begins by forming a trench capacitor in a trench extending in a substrate from a substrate top surface. The trench has a trench side wall and a trench bottom. A trench conductor fills the trench and a node dielectric surrounds the trench side wall. An oxide collar is adjacent to the node dielectric at the upper portion of the trench side wall. Next, a mask is formed on the substrate top surface such that the mask covers a portion of the trench capacitor and leaves a portion of the capacitor exposed. The exposed portions of the trench conductor, node dielectric, and oxide collar are then etched to a point intermediate the substrate top surface and the trench bottom such that a portion of the substrate adjacent the trench side wall is exposed. The mask is next removed and the trench conductor is etched to a second point intermediate the substrate top surface and trench bottom. Next, a polycrystalline silicon layer is grown from the trench conductor while an epitaxial silicon layer is grown from the exposed substrate portion. An access transistor is then formed after shallow trench isolation; the reclaimed epitaxial silicon area is used to form part of the access transistor.

It is to be understood that both the foregoing general description and the following detailed description are exemplary, but are not restrictive, of the invention.

### BRIEF DESCRIPTION OF THE DRAWING

The invention is best understood from the following detailed description when read in connection with the accompanying drawing. It is emphasized that, according to common practice, the various features of the drawing are not to scale. On the contrary, the dimensions of the various features are arbitrarily expanded or reduced for clarity. Included in the drawing are the following figures:

FIG. 1 shows a cross-sectional view of a conventional DRAM cell having a buried strap electrically connecting a transistor and a trench capacitor;

FIG. 2 shows a cross-sectional view of a trench extending in a substrate through a pad insulator, the trench having a collar oxide and a node dielectric formed on the collar dielectric and being filled with a trench conductor;

FIG. 3 shows the structure of FIG. 2 having a mask covering a portion of the trench;

FIG. 4 shows the structure of FIG. 3 in which the exposed portion of the trench has been etched and the exposed portions of the collar oxide and the node dielectric have been etched;

FIG. 5 shows the structure of FIG. 4 in which the mask has been removed and the trench has been etched;

FIG. 6 shows the structure of FIG. 5 having a partially formed polysilicon layer on the trench conductor and a partially formed epitaxial silicon layer on the exposed substrate;

FIG. 7 shows the structure of FIG. 6 in which the completely formed polysilicon layer and the completely formed epitaxial silicon layer fill the trench at the end of the epitaxial reclaim process;

FIG. 8 shows the structure of FIG. 7 in which the top surface of the structure has been planarized;

FIG. 9 shows the structure of FIG. 8 having a shallow trench isolation region on one side of the trench;

FIG. 10 shows the structure of FIG. 9 in which the epitaxial silicon layer is ion implanted to form an active area of the transistor, and a gate has been formed adjacent the trench;

FIG. 11 shows the structure of FIG. 10 in which the width of the active area corresponds to only a portion of the width of the trench; and

FIG. 12 shows the structure of FIG. 10 in which the width of the active area is greater than the width of the trench.

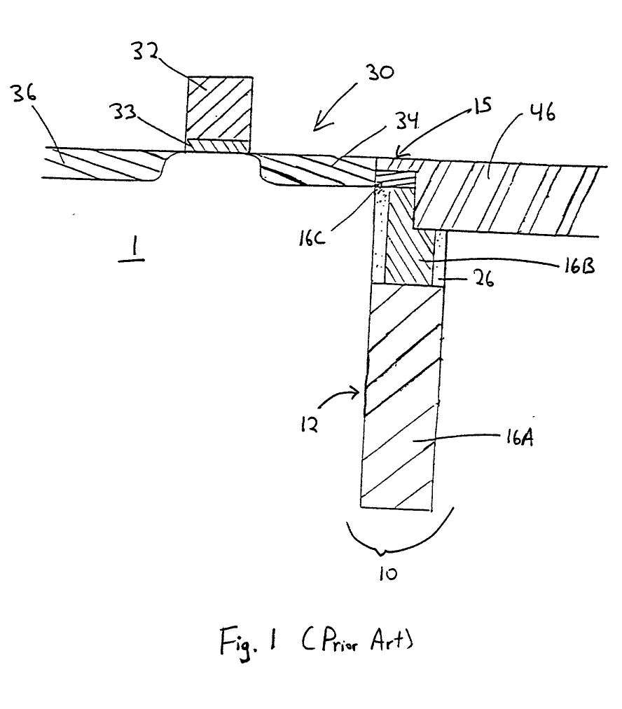

### DETAILED DESCRIPTION OF THE INVENTION

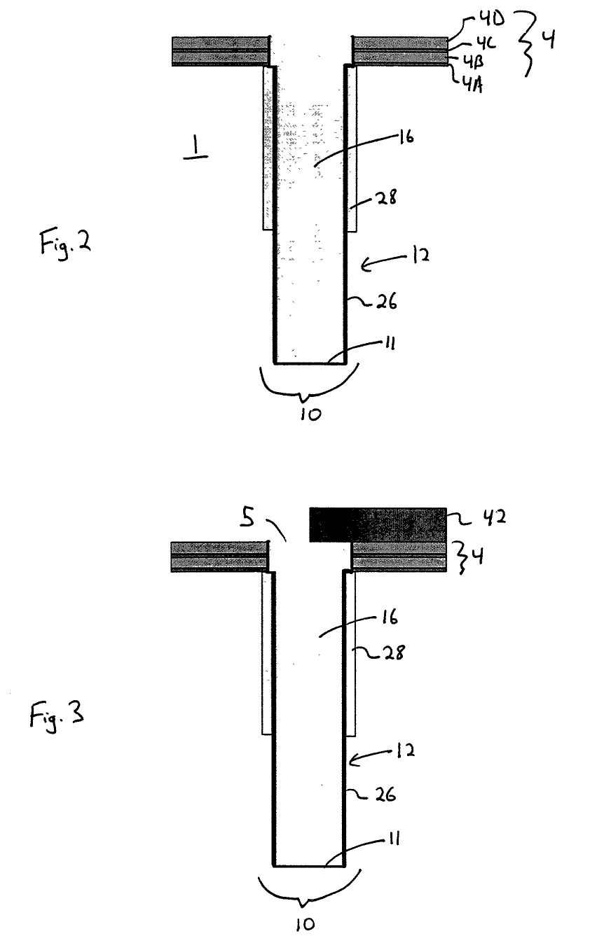

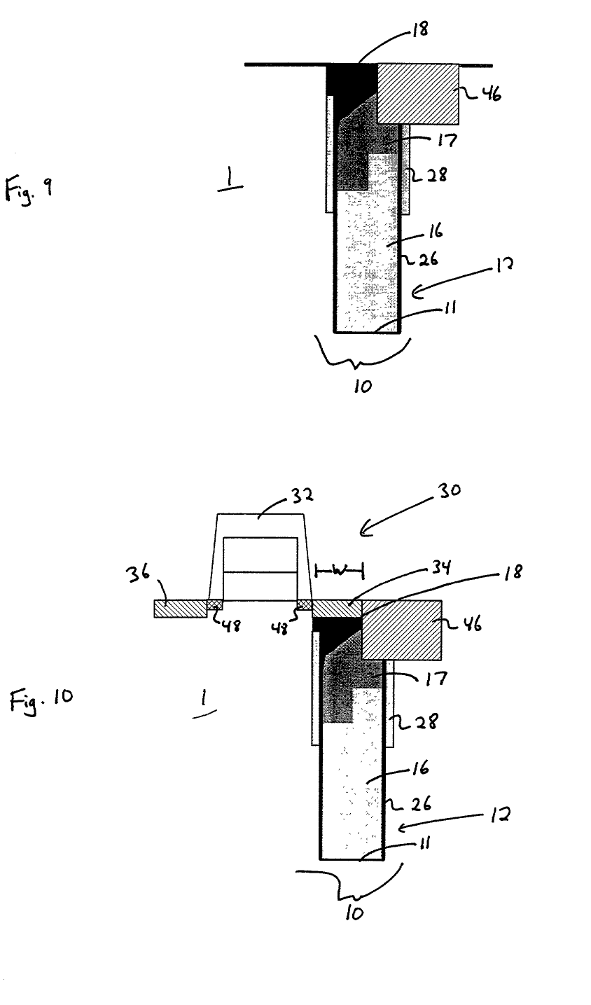

The invention will next be illustrated with reference to the figures in which the same numbers indicate the same elements in all figures. Such figures are intended to be illustrative, rather than limiting, and are included to facilitate the explanation of the process and apparatus of the present invention. FIGS. 10-12 illustrate embodiments of the DRAM cell of the present invention. Structures formed in accordance with the process of the invention are illustrated in FIGS. 2-9.

Referring now to FIG. 2, the process of the invention begins by etching a trench 12 in a substrate. The substrate comprises a single crystalline silicon substrate 1 and preferably also comprises a pad insulator 4 formed on the substrate 1. The pad insulator 4 is illustrated in FIG. 2 as a thin oxide layer 4A, a thin nitride layer 4B, a thin oxide layer 4C, and a thin nitride layer 4D. The pad insulator 4 is formed using techniques known to those of ordinary skill in the art. Although illustrated as having four layers, it should be appreciated that the pad insulator 4 can comprise one, two, or three insulator layers, or the pad insulator 4 can comprise more than four insulator layers. Preferably, the pad insulator 4 comprises an oxide layer having a thickness of about 5 nm and a nitride layer having a thickness of about 200 nm.

The depth of the trench 12 formed in the substrate 1 is determined based on the desired capacitance of the trench capacitor 10. The trench 12 has a bottom 11 and is lined with a node dielectric barrier 26. In addition, the upper portion of the trench 12 is lined with a collar oxide 28 adjacent the node dielectric barrier 26. The trench 12 is also filled with a trench conductor 16 to form the trench capacitor 10. The trench conductor 16 is a polysilicon material. In order to obtain a planar top surface, it may be necessary to planarize the trench conductor 16, such as by chemical mechanical planarization (CMP). The structure illustrated in FIG. 2 can be formed using methods that are well known to those of ordinary skill in the art.

In the next step of the process of the invention, a mask 42 is positioned such that the mask 42 covers a portion of the trench capacitor 10 and leaves a portion of the trench capacitor 10 exposed. The mask 42 is formed using techniques well known to those of ordinary skill in the art. Although not required, the mask 42 may also cover a portion of the top surface 5 of the substrate 1, as illustrated in FIG. 3.

The mask 42 blocks a portion of the trench capacitor 10 during the subsequent step of etching the exposed portions of the trench conductor 16, node dielectric barrier 26, and collar oxide 28. Those masks conventionally used as block out masks can be used in the process of the invention. A suitable mask material is boron silicate glass (BSG).

Following formation of the mask 42, the exposed portions of the trench conductor 16, node dielectric 26, and collar oxide 28 are etched to a point intermediate the top surface 5 of the substrate 1 and the bottom 11 of the trench 12. The etch step forms a recess 40 such that a portion 3 of the single crystalline silicon substrate 1 is exposed. The resulting structure is illustrated in FIG. 4.

It is to be noted that the mask 42 in FIG. 4 allows the exposure of only a single crystallographic plane, namely exposed silicon portion 3, of the single crystalline silicon substrate 1. The use of a single crystallographic plane for the epitaxial growth offers the advantage of minimal defect generation during the selective epitaxial reclaim process. An important feature of the present invention is the growth of the epitaxial layer 18 from a single plane.

The trench conductor 16 portion is removed using techniques well known to those of ordinary skill in the art. Preferably, the trench conductor 16 is etched using reactive ion etching (RE). Portions of the node dielectric barrier 26 and collar oxide 28 are also removed using techniques well known to those of ordinary skill in the art, such as wet etching. During removal of the portions of the node dielectric barrier 26 and the collar oxide 28, it is permissible to also etch a portion of mask 42 adjacent the recess 40. Preferably, the collar oxide 28 portion is removed using a BEF etch.

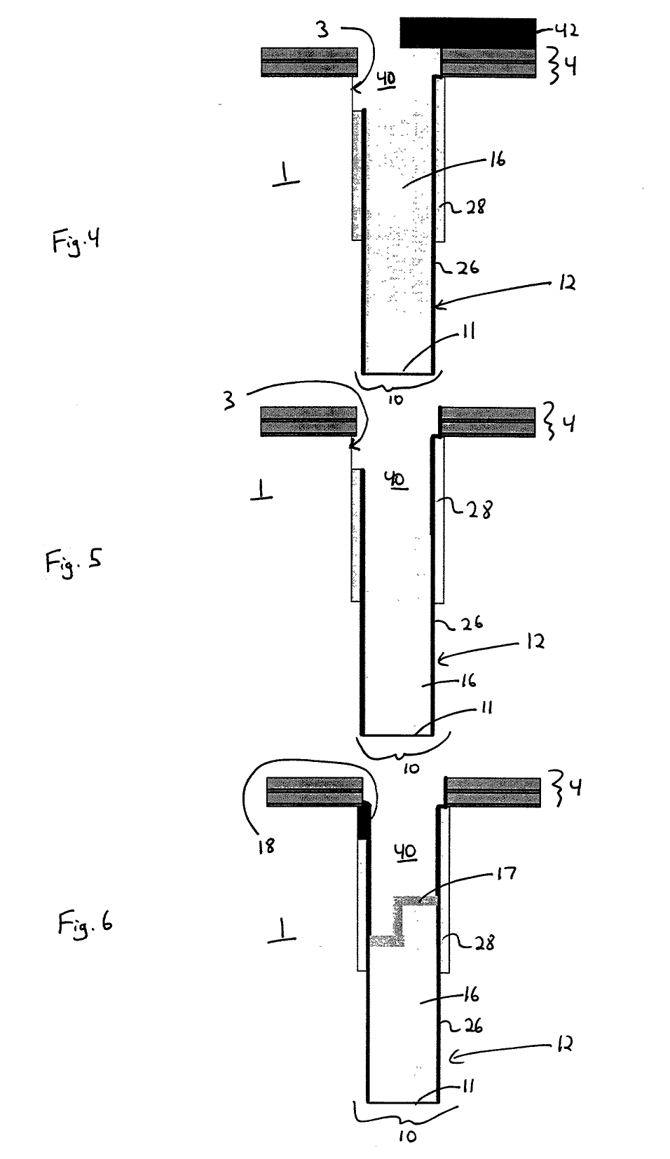

After formation of the recess 40, the mask 42 is removed and the trench conductor 16 is etched to a second point intermediate the top surface 5 of the substrate 1 and the trench bottom 11. The trench conductor 16 can be etched using conventional techniques and preferably is etched using a reactive ion etch (RIE) selective to the node dielectric barrier 26 and the collar oxide 28. The resulting structure is illustrated in FIG. 5.

In the next step of the process of the invention, polycrystalline silicon is grown from the exposed portion on the trench conductor 16 to form the polysilicon layer 17 and epitaxial silicon 18 is selectively grown from the exposed portion 3 of the single crystalline silicon substrate 1. The polysilicon layer 17 and the epitaxial silicon layer 18 are grown simultaneously. The resulting structure is illustrated in FIG. 6.

The growth of the polysilicon layer 17 and the growth of the epitaxial silicon layer 18 proceed simultaneously and are selective to the node dielectric barrier 26 and the collar oxide 28. In other words, no growth occurs on either the collar oxide 28 or the node dielectric barrier 26. Conventional selective silicon epitaxy processes, such as selective silicon epitaxial growth using dichlorosilane (SiH₂Cl₂) and hydrogen chloride (HCl) at about 800° C., may be used for this purpose. When the node dielectric barrier 26 and the collar oxide 28 are composed of silicon dioxide, silicon nitride, or both, epitaxial silicon is grown on the epitaxial substrate and polycrystalline silicon is grown on the doped polysilicon in the trench 12, but growth does not occur on the node dielectric barrier 26 or on the collar oxide 28. It should be appreciated that the above process serves only as an example. The present invention is not limited to the above growth process and any selective silicon growth process may be used.

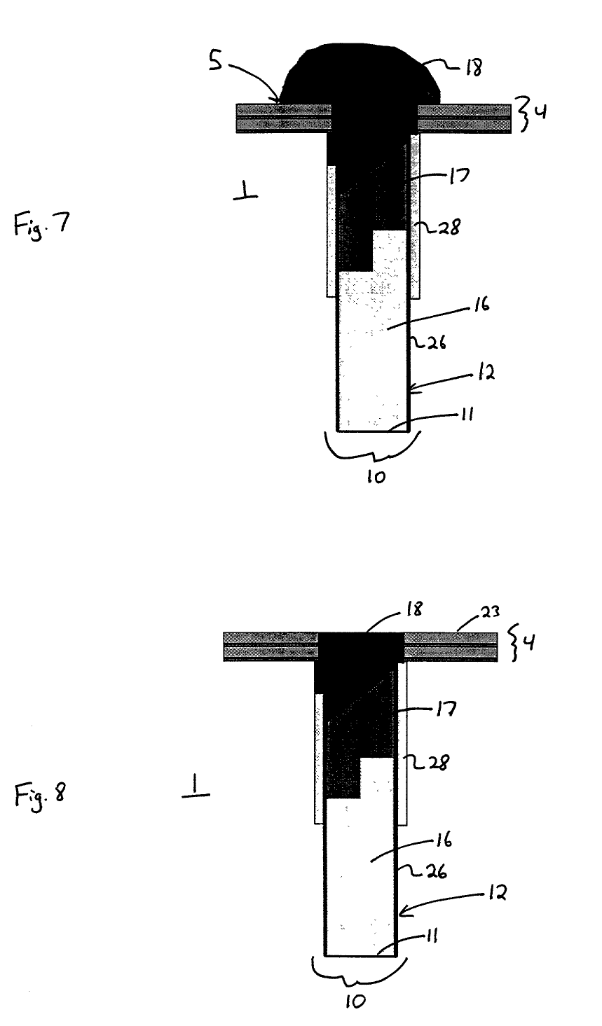

As shown in FIG. 7, the polysilicon layer 17 and the epitaxial silicon layer 18 are grown such that they fill the recess 40. It has been discovered that the buried strap 16C conventionally formed in a substrate between the trench capacitor and the access transistor is replaced with a natural electrical connection as the polysilicon layer 17 grown from the trench conductor 16 merges with the epitaxial silicon layer 18 grown from the exposed portion 3 of the single crystalline silicon substrate 1. This design reclaims the valuable silicon real estate above the trench capacitor 10. In addition, this design minimizes the defect migration from polysilicon into epitaxial silicon because the epitaxial-polysilicon interface is formed at a relatively high temperature, such as above 800° C., which stabilizes the structure of the polysilicon layer 17 as it grows over the trench conductor 16.

Furthermore, in contrast to conventional DRAM cell designs using a thin barrier layer before polysilicon deposition to suppress trench polysilicon induced dislocation during and after buried strap formation, the present invention does not add any interfacial layers to increase the overall buried strap resistance. The present invention uses selective epitaxial silicon to fill the recess 40. Thus, the present invention reduces both polysilicon defect induced leakage and strap resistance, and improves signal formation.

FIG. 7 illustrates the resulting structure. The epitaxial silicon layer 18 and the polysilicon layer 17 have merged in the trench 12 and the epitaxial silicon layer 18 has grown out onto the top surface 5 of the substrate 1. When this occurs, the pad insulator 4 can be planarized using conventional planarization techniques, such as chemical mechanical planarization (CMP), to produce the structure illustrated in FIG. 8. As illustrated, the pad insulator 4 has a planar top surface 23.

Next, the pad insulator 4 is removed and then the surface can optionally be planarized to form a flat surface. A shallow trench isolation (STI) region 46 is then formed using techniques well known to those of ordinary skill in the art. The STI region 46 is planarized and any excess epitaxial silicon can be removed by planarization of the STI region 46. This process step results in the structure illustrated in FIG. 9.

Following formation of the STI region 46, the gate 32 of the transistor 30 is formed adjacent the trench capacitor 10. The gate 32 is formed using techniques well known to those of ordinary skill in the art. In addition, the source 34 and drain 36 of the access transistor 30 are formed adjacent the gate 32. One of the source or drain is formed by doping at least a portion of the epitaxial silicon layer 18. As shown in FIGS. 10-12, doping of the epitaxial silicon layer 18 produces an active area which is (for example) the source 34 of the transistor 30. An active area extension region 48 can be formed adjacent the trench capacitor 10 before formation of the gate 32 and the source 34 using conventional techniques.

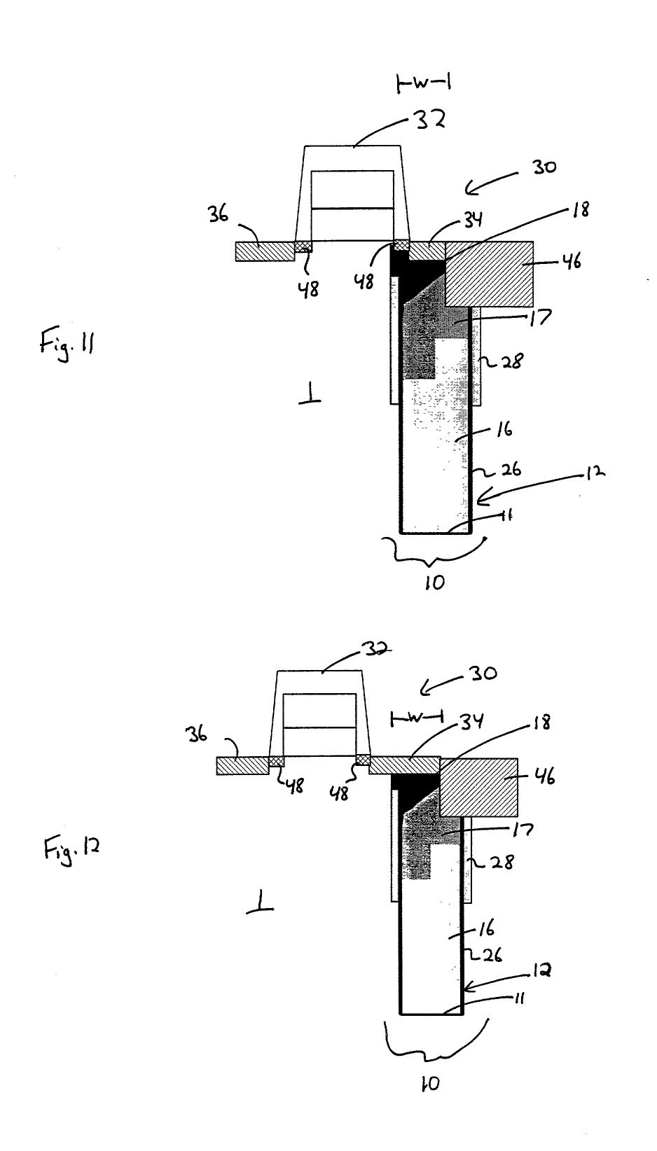

As shown in FIG. 10, the source 34 can occupy the entire width “W” of the trench capacitor 10. Alternatively, the source 34 can occupy less than the full width “W” of the trench capacitor 10, as illustrated in FIG. 11. Furthermore, as illustrated in FIG. 12, the source 34 can have a width which is greater than the width “W” of the trench capacitor 10.

Thus, a feature of the present invention is that the position of the access transistor 30 is such that one of the active areas (source or drain) is formed either partially or fully within the epitaxially reclaimed silicon that is positioned over the trench capacitor 10. This configuration results in savings in the silicon grown from the trench 12. Implantation below the active area may be used to augment the electrical connection between the active area and the polysilicon layer 17. Thus, the present invention provides a DRAM cell design that reclaims the active area above the trench capacitor 10. The invention also provides a process of manufacturing this DRAM cell design.

Although illustrated and described above with reference to specific embodiments, the present invention is nevertheless not intended to be limited to the details shown. Rather, various modifications may be made in the details within the scope and range of equivalents of the claims and without departing from the spirit of the invention.

What is claimed is:

1. A dynamic random-access memory (DRAM) cell comprising:
a substrate having a top surface and a trench with a trench bottom in the substrate, the trench extending from the top surface of the substrate to the trench bottom;
a trench capacitor positioned in the trench at the bottom of the trench; and
an access transistor having an active area formed in the trench adjacent the trench capacitor and adjacent the top surface of the substrate, the active area being in electrical connection with the trench capacitor.

2. The dynamic random-access memory cell of claim 1 wherein the substrate comprises single crystalline silicon.

3. The dynamic random-access memory cell of claim 1 wherein the active area is one of a source and a drain of the transistor.

4. The dynamic random-access memory cell of claim 1 wherein the active area comprises epitaxial silicon.

5. The dynamic random-access memory cell of claim 1 further comprising a shallow trench isolation region on one side of the trench capacitor opposite the transistor.

6. A process for manufacturing a dynamic random-access memory (DRAM) cell, the process comprising the steps of:
(a) forming a trench capacitor of the cell, the trench capacitor comprising:
a trench extending in a substrate from a substrate top surface, the trench having a trench side wall and a trench bottom,
a trench conductor filled in the trench,
a node dielectric surrounding the trench side wall, and
an oxide collar adjacent to the node dielectric at an upper portion of the trench side wall;
(b) forming a mask on the substrate top surface, the mask covering a portion of the trench capacitor and leaving a portion of the trench capacitor exposed;
(c) etching the exposed portion of the trench conductor, the node dielectric, and the oxide collar to a point intermediate the substrate top surface and the trench bottom such that a portion of the substrate adjacent the trench side wall is exposed;
(d) removing the mask and etching the trench conductor to a second point intermediate the substrate top surface and the trench bottom;
(e) selectively growing a polycrystalline silicon layer from the trench conductor and selectively growing an epitaxial silicon layer from the exposed substrate portion; and
(f) forming the access transistor of the cell by doping the epitaxial silicon layer to form one of a source and a drain of the transistor and creating a gate and the other of the source and the drain adjacent thereto.

7. The process of claim 6 wherein the substrate comprises single crystalline silicon having a pad insulator layer formed thereon and wherein the pad insulator is removed before step (f).

8. The process of claim 7 wherein the pad insulator comprises an oxide layer having a thickness of about 5 nm and a nitride layer having a thickness of about 200 nm.

9. The process of claim 6 wherein the trench conductor is polysilicon.

10. The process of claim 6 wherein step (c) comprises:
(i) reactive ion etching (RIE) the trench conductor to expose a portion of the oxide collar and a portion of the node dielectric; and
(ii) wet etching the exposed portion of the oxide collar and the exposed portion of the node dielectric to expose the substrate portion adjacent the trench side wall.

11. The process of claim 6 wherein the etching in step (d) comprises reactive ion etching (RIE) the trench conductor.

12. The process of claim 6 further comprising the step of planarizing the substrate top surface and the epitaxial silicon layer before step (f).

13. The process of claim 6 further comprising the step of forming a shallow trench isolation (STI) region on one side of the trench capacitor before the step (f).

14. A dynamic random-access memory structure formed by a process comprising the steps of:
(a) forming a trench capacitor, the trench capacitor comprising:
a trench extending in a substrate from a substrate top surface, the trench having a trench side wall and a trench bottom,
a trench conductor filled in the trench,
a node dielectric surrounding the trench side wall, and
an oxide collar adjacent the node dielectric at an upper portion of the trench side wall;
(b) forming a mask on the substrate top surface, the mask covering a portion of the trench capacitor and leaving a portion of the trench capacitor exposed;
(c) etching the exposed portion of the trench conductor, the node dielectric, and the oxide collar to a point intermediate the substrate top surface and the trench bottom such that a portion of the substrate adjacent the trench side wall is exposed;
(d) removing the mask and etching the trench conductor to a second point intermediate the substrate top surface and trench bottom;
(e) selectively growing a polycrystalline silicon layer from the trench conductor and selectively growing an epitaxial silicon layer from the exposed substrate portion; and
(f) forming an access transistor by doping the epitaxial silicon layer to form one of a source and a drain of the transistor and creating a gate and the other of the source and the drain adjacent thereto.

15. The dynamic random-access memory cell of claim 14 wherein the substrate comprises single crystalline silicon having a pad insulator layer formed thereon and wherein the pad insulator is removed before step (f).

16. The dynamic random-access memory cell of claim 14 wherein the trench conductor is polysilicon.

17. The dynamic random-access memory cell of claim 14 wherein step (c) comprises:
(i) reactive ion etching (RIE) the trench conductor to expose a portion of the oxide collar and a portion of the node dielectric; and
(ii) wet etching the exposed portion of the oxide collar and the exposed portion of the node dielectric to expose the substrate portion adjacent the trench side wall.

18. The dynamic random access memory cell of claim 14 wherein the etching in step (d) comprises reactive ion etching (RIE) the trench conductor.

19. The dynamic random access memory cell of claim 14 further comprising the step of planarizing the substrate top surface and the epitaxial silicon layer before step (f).

20. The dynamic random-access memory cell of claim 14 further comprising the step of forming a shallow trench isolation (STI) region on one side of the trench before the step (f).
